(19) United States
(12) Patent Application Publication
(10) Pub. No.: US 2016/0002770 A1
(43) Pub. Date: Jan. 7, 2016

(54) APPARATUS WITH NEIGHBORING SPUTTER CATHODES AND METHOD OF OPERATION THEREOF

(71) Applicants: Fabio PIERALISI, (US); Uwe MÜHLFELD, (US); Applied Materials, Inc., Santa Clara, CA (US)

(72) Inventors: Fabio PIERALISI, Aschaffenburg (DE); Uwe MÜHLFELD, Wörth (DE)

(21) Appl. No.: 14/767,258

(22) PCT Filed: Feb. 25, 2013
(86) PCT No.: PCT/EP2013/053733

§ 371 Date: Aug. 11, 2015

(51) Int. Cl. C23C 14/56; C23C 14/54; C23C 14/50; C23C 14/14; H01J 37/34; C23C 14/35

(52) U.S. Cl. CPC C23C 14/568; H01J 37/345; C23C 14/35; C23C 14/50; C23C 14/14; C23C 14/542; H01J 37/3435

(57) ABSTRACT

An apparatus for deposition of a layer stack on a non-flexible substrate or on a substrate provided in a carrier is described. The apparatus includes a vacuum chamber, a transport system, wherein the transport system and the vacuum chamber are configured for inline deposition, a first support for a first rotatable sputter cathode rotatable around a first rotation axis within the vacuum chamber, wherein a first deposition zone for depositing a first material is provided, a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below; and a separator structure between the first rotation axis and the second rotation axis, adapted to receive the first material sputtered towards the second deposition zone and the second material sputtered towards the first deposition zone, wherein apparatus is configured for deposition of the layer stack comprising a layer of the first material and a subsequent layer of the second material.

### TECHNICAL FIELD OF THE INVENTION

Embodiments of the present invention relate to sputtering equipment, apparatuses and systems, and methods of operating thereof Embodiments of the present invention particularly relate to apparatuses for deposition of a layer stack on a non-flexible substrate or on a substrate provided in a carrier, systems for deposition of materials on a non-flexible substrate or on a substrate provided in a carrier, and methods of depositing a layer stack on a non-flexible substrate or on a substrate provided in a carrier.

### BACKGROUND OF THE INVENTION

Several methods are known for depositing a material on a substrate. For instance, substrates may be coated by a physical vapor deposition (PVD) process, a chemical vapor deposition (CVD) process, a plasma enhanced chemical vapor deposition (PECVD) process, etc. Typically, the process is performed in a process apparatus or process chamber, where the substrate to be coated is located. A deposition material is provided in the apparatus. A plurality of materials, but also oxides, nitrides or carbides thereof may be used for deposition on a substrate.

Coated materials may be used in several applications and in several technical fields. For instance, an application lies in the field of microelectronics, such as generating semiconductor devices. Also, substrates for displays are often coated by a PVD process. Further applications include insulating panels, organic light emitting diode (OLED) panels, substrates with TFT, color filters or the like. Further, also manufacturing of motherboards and packaging of semiconductors utilizes thin-film deposition, and particularly deposition of various metal layers.

Typically, a plurality of processes are conducted in a deposition system having a plurality of chambers. Thereby, one or more load lock chambers can be provided. Further, typically a plurality of deposition chambers are provided in the system in order to deposit various layers on a substrate.

In conventional dynamic sputter coaters, wherein the substrates travel in front of the sputtering cathodes, multilayer deposition of different materials is carried out in multiple process chambers, i.e. using a process chamber for each of the materials to be deposited in order to avoid material intermixing. However, cost of ownership and footprint of deposition systems is a consideration, for which continuous effort for improvement is desired.

### SUMMARY OF THE INVENTION

In light of the above an apparatus for deposition of a layer stack on a non-flexible substrate or on a substrate provided in a carrier, a system for deposition of materials on a non-flexible substrate or on a substrate provided in a carrier, and a method of depositing a layer stack on a non-flexible substrate or on a substrate provided in a carrier are provided. Further aspects, advantages, and features of the present invention are apparent from the dependent claims, the description, and the accompanying drawings.

According to one embodiment, an apparatus for deposition of a layer stack on a non-flexible substrate or on a substrate provided in a carrier is provided. The apparatus includes a vacuum chamber, a transport system, wherein the transport system and the vacuum chamber are configured for inline deposition, a first support for a first rotatable sputter cathode rotatable around a first rotation axis within the vacuum chamber, wherein a first deposition zone for depositing a first material is provided, a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below; and a separator structure between the first rotation axis and the second rotation axis, adapted to receive the first material sputtered towards the second deposition zone and the second material sputtered towards the first deposition zone, wherein apparatus is configured for deposition of the layer stack comprising a layer of the first material and a subsequent layer of the second material.

According to another embodiment, an apparatus for deposition of a layer stack on a non-flexible substrate or on a substrate provided in a carrier is provided. The apparatus includes a vacuum chamber, a transport system, wherein the transport system and the vacuum chamber are configured for inline deposition, a first support for a first rotatable sputter cathode rotatable around a first rotation axis within the vacuum chamber, wherein a first deposition zone for depositing a first material is provided, a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below, and a separator structure provided between the first deposition zone and the second deposition zone and configured to reduce intermixing of the first material and the second material during deposition, wherein the separator structure extends at least from between the first rotation axis and the second rotation axis and towards the transport system, wherein apparatus is configured for deposition of the layer stack comprising a layer of the first material and a subsequent layer of the second material.

According to a yet further embodiment, a system for deposition of materials on a non-flexible substrate or on a substrate provided in a carrier is provided. The system includes a first load lock chamber for inward transfer of the substrate into the system, an apparatus for deposition of a layer stack on a non-flexible substrate or on a substrate provided in a carrier, and a second load lock chamber for outward transfer of the substrate out of the system. The apparatus for deposition of a layer stack on a non-flexible substrate or on a substrate provided in a carrier includes a vacuum chamber, a transport system, wherein the transport system and the vacuum chamber are configured for inline deposition, a first support for a first rotatable sputter cathode rotatable around a first rotation axis within the vacuum chamber, wherein a first deposition zone for depositing a first material is provided, a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below; and a separator structure between the first rotation axis and the second rotation axis, adapted to receive the first material sputtered towards the second deposition zone and the second material sputtered towards the first deposition zone, wherein apparatus is configured for deposition of the layer stack comprising a layer of the first material and a subsequent layer of the second material.

According to another embodiment, a method of depositing a layer stack on a non-flexible substrate or on a substrate provided in a carrier is provided. The method includes sputtering a first material layer having a first material from a first rotatable sputter cathode, wherein a first portion of the first material released from a first target of the first rotatable sputter cathode is deposited on the substrate, sputtering a second material layer having a second material from a second rotatable sputter cathode, and providing a separator structure, wherein the separator structure receives at least 15%, particularly at least 50% of a portion of the first material other than the first portion of the first material.

According to a further embodiment, a method of depositing a layer stack on a non-flexible substrate or on a substrate provided in a carrier is provided. The method includes sputtering a first material layer having a first material from a first rotatable sputter cathode having a first rotation axis in a first vacuum chamber on the substrate, sputtering a second material layer having a second material from a second rotatable sputter cathode having a second rotation axis in the first vacuum chamber on the substrate, wherein the first rotation axis and the second rotation axis have a distance from each other of 700 mm or below, and providing a separator structure to reduce intermixing of the first material and the second material during deposition of an in-line deposition process, wherein the separator structure extends at least from between the first rotation axis and the second rotation axis and towards the substrate.

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a deposition apparatus for depositing a layer stack with reduced intermixing of the layer materials according to embodiments described herein, wherein two rotatable sputter cathodes and a separator structure or separator plat are provided in one vacuum chamber;

FIG. 2 shows a schematic view of a deposition apparatus for depositing a layer stack with reduced intermixing of the layer materials according to embodiments described herein, wherein two rotatable sputter cathodes with opposite rotation directions and a separator structure or separator plat are provided in one vacuum chamber;

FIG. 3 shows a schematic view of a deposition apparatus for depositing a layer stack with reduced intermixing of the layer materials according to embodiments described herein, wherein two rotatable sputter cathodes with tilted magnet arrangements and a separator structure or separator plat are provided in one vacuum chamber;

FIG. 4 shows a schematic view of a deposition apparatus for depositing a layer stack with reduced intermixing of the layer materials according to embodiments described herein, wherein more than two rotatable sputter cathodes and a separator structure or separator plat are provided in one vacuum chamber;

FIG. 5 shows a different schematic view of a deposition apparatus for depositing a layer stack with reduced intermixing of the layer materials according to embodiments described herein, wherein a separator structure or separator plat is shown;

FIG. 6 shows a different schematic view of a deposition system for depositing a layer stack with reduced intermixing of the layer materials having a deposition apparatus according to embodiments described herein provided therein; and

FIG. 7 shows a flow chart illustrating methods of depositing a layer stack on a non-flexible substrate or on a substrate provided in a carrier according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

FIG. 1 shows a deposition apparatus 100. The deposition apparatus 100 includes a vacuum chamber 102. Typically the vacuum chamber 102 has sidewalls 104, the first side wall portion 105 and second side wall portion 103. The walls form a vacuum tight enclosure, such that a technical vacuum can be provided in the vacuum chamber 102. Typically, the sidewalls 104 allow for connection to neighboring chambers 20, i.e. the respective sidewalls 24 of the neighboring chambers 20. Thereby, according to typical embodiments, which can be combined with other embodiments described herein, the neighboring chambers 20 can be selected from the group consisting of: a load lock chamber, a transfer chamber, a deposition chamber, an etching chamber, and a processing chamber.

The deposition apparatus 100 further includes a transport system 21. According to typical embodiments, which can be combined with other embodiments described herein, the transport system 21 can include a plurality of rollers, a magnetic rail system, and combinations thereof. Typically the transport system 21 is provided in each of the chambers of the deposition system. Thereby, the substrate 10 or a carrier supporting one or more substrates can be transported as indicated by arrow 11 in a continuous or quasi-continuous manner through the deposition system and the deposition apparatus 100.

According to typical embodiments, which can be combined with other embodiments described herein, the apparatuses, systems, and methods as described herein are particularly useful for dynamic deposition process wherein the substrate processing, for example the deposition of a layer stack, is conducted while the substrate moves along one or more deposition systems. Thereby, the dynamic process may include a short time period without substrate movement or a time period with a wobbling substrate movement (back and forth). However, at least a portion of the substrate processing or at least a significant portion of the substrate processing, for example 50% or above, is conducted while the substrate is moved.

FIG. 1 shows the top view of a deposition apparatus 100. Accordingly the deposition apparatus shown in FIG. 1 has a vertical substrate orientation during processing thereof. According to some embodiments, the substrate or carrier might be slightly inclined, for example by 10° or less. However the substrate is essentially vertical. According to alternative embodiments, the apparatuses, systems, and methods according to embodiments described herein can also be applied for a horizontal deposition system. In this case the first side wall portion 105 is lower wall portion, where the second side wall portion 103 is an upper wall portion. The substrate 10 or a respective carrier having one or more substrates supported therein is moved horizontally through the deposition apparatus 100.

According to embodiments described herein, a first rotatable sputter cathode 110 and a second rotatable sputter cathode 114 are provided in the vacuum chamber 102. Accordingly, the deposition apparatus 100 includes a first support and the second support for supporting the respective sputter cathodes during operation. Thereby, the supports are configured to rotate the rotatable cathodes around a respective rotation axis. According to typical embodiments, which can be combined with other embodiments described herein, the sputter cathodes are rotatable sputter cathode which are rotated during operation as indicated by arrows 111 and 115. Further, a magnet arrangement 112 is provided in the first sputter cathode 110 and a magnet arrangement 116 is provided in the second sputter cathode 114. The magnet arrangements allow for magnetron sputtering for deposition of respective thin films on the substrate 10.

Embodiments described herein are particularly useful if the first sputter cathode 110 has a target of the first material and the second sputter cathode 114 has a target of a second material, which is different from the first material. In such cases, common deposition systems included at least two different chambers for depositing the first material in the first chamber and the second material in the second chamber. Thereby, intermixing of the materials can be avoided during deposition. However, each process chamber considerably raises the overall costs of the deposition system, increases the footprint of the deposition system, and further because of the increased length of the deposition system increases the process tact time, which is at least partly given by the time to transport the substrate or a carrier with one or more substrates supported therein through the deposition system.

According to embodiments described herein, in order to reduce costs for sputter deposition system and to reduce and/or minimize process tact time, the multi-layered deposition is conducted in a single deposition chamber, for example vacuum chamber 102, wherein neighboring sputter cathodes, for example cathodes 110 and 114, each deposit the layer of the first material and the second material, respectively, in the same chamber. Thereby, in order to reduce or avoid intermixing of the materials during deposition, a separator structure 120 is provided in the vacuum chamber 102.

According to typical embodiments, the separator structure is provided between the first sputter cathode or the respective rotation axis thereof and the second sputter cathode or the respective rotation axis thereof. Further, the separator structure is adapted to receive and/or block the first material sputtered towards the deposition zone of the second sputter cathodes and to receive and/or block the second material sputtered towards the deposition zone of the first sputter cathode.

Accordingly, according to some embodiments, which can be combined with other embodiments described herein, the separator structure can be a plate shaped structure extending from at least between the rotation axes of the sputter cathodes towards the transport system 21. Thereby, it has to be noted that according to embodiments described herein, the first cathode, the second cathode and the separator structure are provided within one single vacuum chamber 102. Accordingly, the distance of the respective rotation axes of the first sputter cathode and the second sputter cathodes can be 700 mm or below, 500 mm or below, for example 200 mm to 400 mm, such as about 300 mm or about 220 mm. This is indicated by reference sign L in FIG. 1. Thereby, according to some embodiments, which can be combined with other embodiments described herein, the distance from the outer target surface to the separator plate can be about 100 mm or below, e.g. about 30 mm and/or the distance of the respective outer surfaces of the outer target surfaces can be 200 mm or below, e.g. about 60 mm. Yet further, according to some embodiments, which can be combined with embodiments described herein, the ratio of the distance of the axes of the two cathodes to the diameter of at least one of the two cathodes can be 2.5 or below, e.g. 2 or below.

The separator plate receives a portion of the first material, which is sputtered towards the deposition zone of the second target and vice versa. Thereby, from a target of a sputter cathode an amount of first material is released. A first portion of the released material is deposited on the substrate as desired. The remaining portion, i.e. the portion of the released material that is not deposited on the substrate is deposited e.g. on a carrier, between two carriers, a mask or shield, and on the separator plate. Particularly for the configurations, with a main or average deposition direction inclined away from the separator plate, at least 15% of the remaining portion is received by the separator plate. For embodiments, where the main or average deposition direction is parallel to the separator plate, 30% or more can be received by the separator structure.

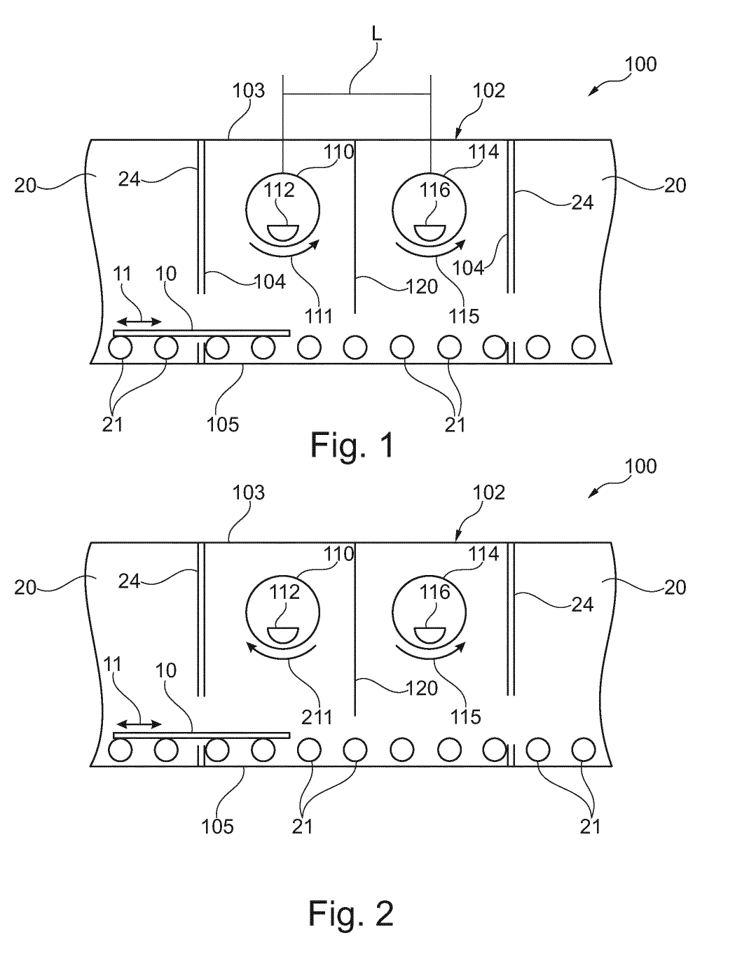

FIG. 2 shows another deposition apparatus 100. Thereby, as compared to the deposition apparatus 100 shown in FIG. 1, the first sputter cathode 110 rotates in the direction indicated by arrow 211. Thereby, the rotation direction on the side of the cathode facing the substrate 10 or a respective carrier is directed away from the separator structure 120 for both of the sputter cathodes 110 and 114. Accordingly, the rotation directions 211 and 115 are configured to reduce material deposition on the separator structure 120. As described in more detail below, the dimension and position of the separator structure 120 can be configured such that the reduced probability of intermixing due to the rotation directions shown in FIG. 2 are taking into account.

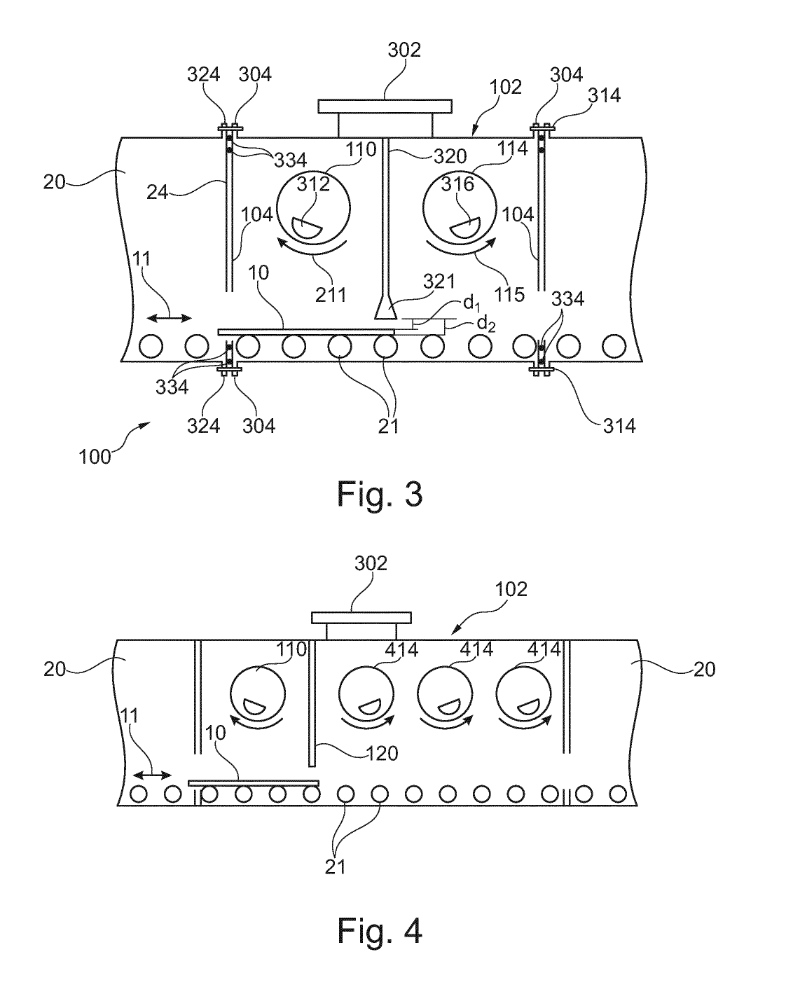

FIG. 3 shows a yet further deposition apparatus 100. Thereby, in addition to the rotation directions 211 and 115, which are directed away from the separator structure on the side facing the substrate, the substrate support, or a carrier having the substrates supported therein, the magnet arrangements 312 and 316 are tilted away from the separator structure 320. According to different embodiments, which can be combined with other embodiments described herein, the rotation direction of the sputter cathodes as described with respect to FIGS. 2 and 3 and the tilt of the magnet arrangements can be utilized alternatively or in combination with each other. Both measures result in a main or average deposition direction, which is tilted away from the separator structure. Thereby, the risk of intermixing of the first material and the second material is reduced and the size, position, or other configurations of the separator structure can be adapted to take into account the reduced probability of intermixing. Further, one or both of these measures are beneficial as they reduce intermixing and can allow for deposition of two materials in the same vacuum chamber with reduced intermixing, such that a layer stack can be provided from sputter cathodes provided in one vacuum chamber.

The separator structure 320 shown in FIG. 3 has plate shaped portion and a widened end portion 321, which allows for increased receipt of the respective materials from the sputter cathodes. Thereby, the intermixing can be further reduced.

According to typical embodiments, the distance of the end portion of the separator structure 320, or of the end of another separator structure 120 as described herein, can be 50 mm or below, for example 5 mm to 25 mm. This distance is indicated by reference d1 in FIG. 3. Accordingly, the distance to the substrate support plane provided by the transport system 21, which is shown by reference sign d2, can be 70 mm or below, for example 25 mm to 45 mm, wherein the carrier thickness of 20 mm has been considered. Yet further, the transport system can also be described as being configured to provide a deposition plane, i.e. the plane in which the surface of the substrate to be processes is located during operation. Accordingly, the deposition plane has the distance d1 from the separator structure during operation.

As described herein, two or more sputter cathodes with targets having different materials are provided within the vacuum chamber 102. Thereby, the apparatus is configured for depositing a layer stack, i.e. second layer over a first layer, wherein intermixing of the materials should be reduced or avoided in order to provide the desired layer stack properties. Thereby, according to different options, the term vacuum chamber or single vacuum chamber can be defined by several options. For example, the vacuum chamber 102 shown in FIG. 3 has one vacuum flange 302. That is, only one single vacuum flange 302, e.g. a vacuum flange provided at about in the middle of the chamber along one direction, is provided for evacuating the chamber in which the at least two deposition sources are provided. As another example, the sidewalls 104 of the vacuum chamber 102 has flange portions 304 such that the vacuum chamber 102 can be connected to neighboring chambers 20 with corresponding flange portion 324 of the neighboring chamber. For example, a plurality of screws 314 can be used around the perimeter of the chambers in order to connect the vacuum chamber 102 two one or more neighboring chambers 20. According thereto, a vacuum chamber 102 has two sidewalls 104, i.e. only two sidewalls 104, with flanges for connections to neighboring chambers. Yet further, as shown in FIG. 3, one or more seals 334 are provided between the vacuum chamber 102 and respective neighboring chambers 20. FIG. 3 shows two O-rings, which extend along the perimeter of the chamber. Typically, O-rings or other seals are provided in grooves or recesses at the sidewalls of the vacuum chambers. Accordingly, embodiments described herein, have two sidewalls 104, i.e. only two sidewalls 104 with grooves, recesses or otherwise treated surfaces for receiving of the seal. Yet further, the separator structures described herein can further be distinguished to the wall of a vacuum chamber having a thickness which is 15 mm or below. That is, the separator structure has the thickness that is not sufficient to form the wall of a vacuum chamber to provide the desired technical vacuum. Further, the walls of the vacuum chamber are typically covered with one or more shieldings. Contrary thereto the separator plate is just a shield without the wall portion capable of forming a vacuum enclosure of a thin-film deposition system.

Thereby, it also needs to be considered that the carriers or substrates and, thus, the walls of the chamber are typically of large size. The larger one of the dimensions of the chamber are according to some embodiments, which can be combined with other embodiments described herein, at least 2 m, typically at least 3 m. Thereby, large area substrates or carriers can be processes. According to some embodiments, large area substrates or carriers may have a size of at least 0.174 m². Typically the size can be about 1.4 m² to about 8 m², more typically about 2 m² to about 9 m² or even up to 12 m².

FIG. 4 shows another deposition apparatus with a vacuum chamber 102 and neighboring chambers 20, wherein the substrate 10 is moved as indicated by arrow 11 over the transport system 21. Thereby, the first cathode 110 is separated by separation structure 120, for example a plate, with respect to the neighboring cathodes 414. According to some embodiments described herein, one, two, or more cathodes 414 can be provided. The example shown in FIG. 4 shows three cathode 414 which are separated from cathode 110 by separator structure 120. Thereby, the first target material is provided for cathode 110 and each of the cathodes 414 have a target with a second material, which is different from the first material. Accordingly, the layer stack can be deposited to have the thinner first layer of the first material and a thicker second layer of the second material. A similar arrangement can be utilized if the deposition rate of the second material is lower as compared to the deposition rate of the first material. FIG. 4 shows the vacuum chamber 102 having one vacuum flange 302 thereby, it is indicated that the cathodes and the separator structure our all provided within one vacuum chamber.

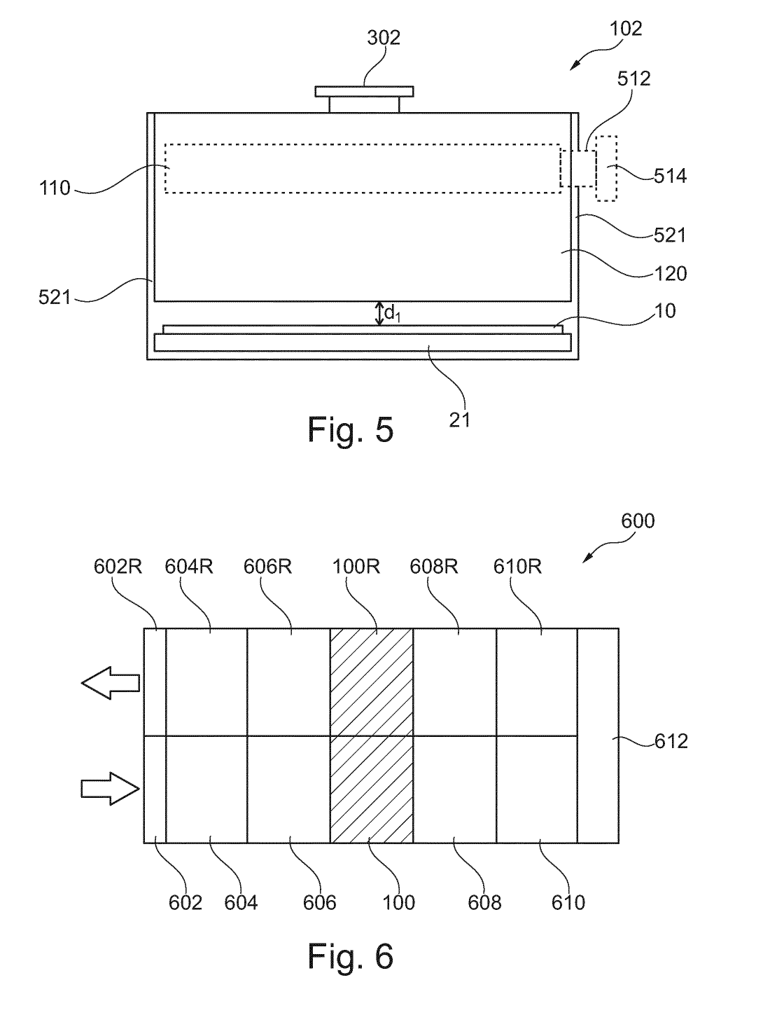

FIG. 5 shows another schematic view of the vacuum chamber 102. Thereby, the transport system 21 is provided such that the substrate 10 or a respective carrier moves in a direction perpendicular to the paper plane in FIG. 5. The cathode 110, respective bearing for the cathode and the drive 514 for the cathode are shown as dotted lines. The vacuum flange 302 is provided at the chamber such that the chamber is configured to be evacuated.

As shown in FIG. 5 and according to some embodiments, which can be combined with other embodiments described herein, the separator structure 120, e.g. a plate, is provided in the vacuum chamber 102 such that a gap is provided between the separator structure and at least two wall of the chamber, typically, three walls of the chamber. In FIG. 5 the three walls are the wall towards the transport system, where a distance d1 is provided between the separator structure 120 and the substrate 10, and the two side walls, where the gaps 521 are shown. Accordingly, the separator structure is provided with gaps. The two regions having the cathode with the first material and the cathode with the second material provided therein can both be easily evacuated utilizing one vacuum flange 302. The width of the inner portion of the chamber (from left to right in FIG. 5) can be about 3 m, whereas the corresponding dimension of the separator plate is about 2.8 m. Thus, according to typical embodiments, the dimension of the separator plate in a direction parallel to the axis of the rotatable sputter target can be about 85% to 99% of the corresponding inside dimension of the vacuum chamber.

According to yet further embodiments, which can be combined with other embodiments described herein, instead of a gap a contact between the side wall of the chamber and the separator structure 120 can be provided. However, in this case, the contact area is not sealed and/or soldered. According to yet further embodiments, which can be combined with other embodiments described herein, the separator structure is provided, such that the processing gas mixture and the processing atmosphere on the opposing sides of the separator structure is essentially similar.

FIG. 6 shows a deposition system 600. According to embodiments described herein, a deposition system includes at least one deposition apparatus according to embodiments described herein. FIG. 6 shows exemplarily two deposition apparatuses 100 and 100R, which can be provided as for example shown in FIGS. 1 to 5. Generally, the system 600 includes to neighboring deposition lines, wherein one is provided for a first direction of substrate movement and the other line is provided for a reverse substrate movement. This is indicated by the arrows. Thereby, the chamber 612 can be rotation module such as a vacuum rotation module. The substrate can be transferred from on line, e.g. the lower line in FIG. 6 to the upper, reverse line in FIG. 6.

The system 600 includes a load lock 602, such that a substrate or a carrier supporting one or more substrates can be loaded in the system. The chambers 604 are transfer chambers, such that the loading process and evacuation of the plurality of chambers can be provided in order to have a dynamic deposition process after the loading. In order to have one or more chambers connected and evacuated for processing of the substrate, the load lock need to be opened towards atmosphere. Then the substrate or carrier can be inserted in the system, the load lock can be closed and the first transfer chamber can be evacuated. Before the load lock can be opened for introducing the next substrate or the next carrier in the system, the substrate is transferred in the second transfer chamber 606 such that first transfer chamber 604 can be vented.

According to embodiments described herein, a layer stack included two layers of different materials is deposited in deposition apparatus 100, i.e. one vacuum chamber with at least two different sputter cathodes and a separator structure between the cathodes. Thereby, intermixing of the two materials can be avoided or significantly reduced. Thereafter in chamber 608 a further substrate processing step, e.g. an ion treatment can be provided.

Chamber 610, 612, and 610R are further transfer chambers for providing a transfer from the lower line in FIG. 6 to the upper line in FIG. 6. In the upper line further processing and/or deposition chambers are provided before the substrate is moved out of the system through load lock 602R via transfer chambers 604R and 606R.

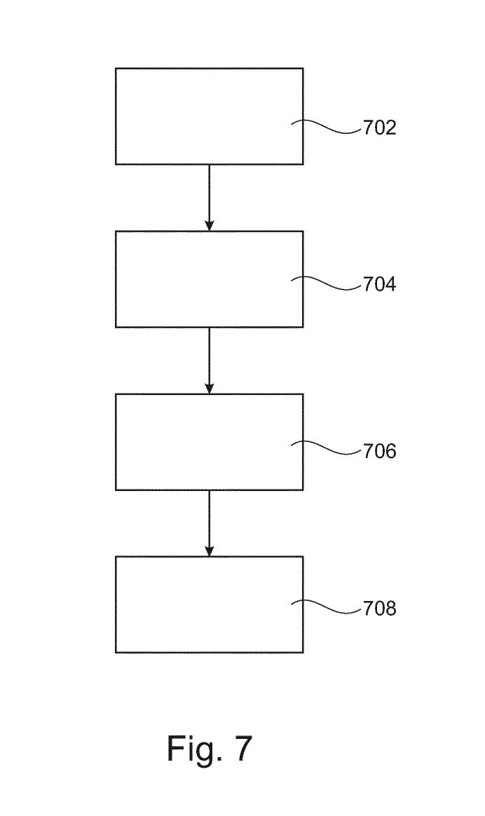

FIG. 7 illustrates an example of an embodiment of depositing a layer stack on a non-flexible substrate or on a substrate provided in a carrier and can be used to describe yet further embodiments. In step 702 a first material layer having a first material from is sputtered a first rotatable sputter cathode having a first rotation axis in a first vacuum chamber on the substrate. In step 704 a second material layer having a second material is sputtered from a second rotatable sputter cathode having a second rotation axis in the first vacuum chamber on the substrate. Thereby, a separator structure is provided between the first rotation axis and the second rotation axis and is adapted to receive the first material sputtered towards the second deposition zone and the second material sputtered towards the first deposition zone. The separator plate is provided to reduce intermixing of the first material and the second material during deposition of an in-line deposition process, wherein the separator plate extends at least from between the first rotation axis and the second rotation axis and towards the substrate.

According to additional or alternative modifications thereof, the rotary sputter cathodes can be rotated in opposing directions in step 706, i.e. clockwise and counter-clockwise respectively and/or the magnet arrangements can be tilted away or provided in an orientation tilted away from the separator structure in step 708.

Accordingly, embodiments described herein relate to apparatuses and methods for deposition of a layer stack on a non-flexible substrate or on a substrate provided in a carrier. A first support for a first rotatable sputter cathode rotatable around a first rotation axis within the vacuum chamber, wherein a first deposition zone for depositing a first material is provided, and a second support for a second rotatable sputter cathode rotatable around a second rotation axis within the vacuum chamber, wherein a second deposition zone for depositing a second material is provided, are provided. The cathodes are provided in one chamber and thereby, the first rotation axis and the second rotation axis can have a distance from each other of 500 mm or below. A separator structure between the first rotation axis and the second rotation axis is provided, which is adapted to receive the first material sputtered towards the second deposition zone and the second material sputtered towards the first deposition zone. Thereby, intermixing of the materials of subsequent layers can be reduced or avoided.

According to typical embodiments, which can be combined with other embodiments described herein, the first material layer is a metallic layer and the second material layer is a metallic layer, particularly, wherein the first material layer is selected from the group consisting of: Ti, NiV, and Mo and the second material layer is selected from the group consisting of: Cu, Al, Au, Ag. According to yet further embodiments, which can be combined with other embodiments described herein, also alloys of these materials, e.g. Al:Nd, Mo:Nb etc., can be provided as the first material and/or the second material.

According to yet further embodiments, which can be combined with other embodiments described herein, the deposited first material and/or the deposited second materials can be non-reactively deposited, i.e. can be a non-reactively deposited material. For example, the first deposition process in the vacuum chamber can be a non-reactive deposition process and the second deposition process in the vacuum chamber can be a non-reactive deposition process. It might be possible that according to some embodiments either one or both of the first and second deposition processes can also be a reactive deposition process. Yet, adjustment of the desired atmosphere(s) in the vacuum chamber and/or desired working parameters might be complex if one or more reactive deposition processes are conducted in the vacuum chamber. Accordingly, typically, two non-reactive deposition processes are provided according to embodiments described herein, and the apparatuses according to embodiments described herein are configured for conducting two non-reactive deposition processes.

Typically, the first metallic layer can be an adhesion layer for the second metallic layer. The adhesion layer can have a thickness of 100 nm or below. The second metallic layer can have a thickness of 300 nm to 1000 nm or 500 nm or below, e.g. about 500 nm. Thereby, the second metallic layer can be deposited to form a seed layer on the adhesion layer. The seed layer enables the following electroplating process. According to typical embodiments, which can be combined with other embodiments described herein, the first layer and the second layer are metallic layers, which is e.g. contrary to an oxide layer formed of oxides of an element. Specifically, a combination of Ti as an adhesive layer and Cu as a seed layer can be formed. Accordingly, the embodiments described herein can be used to form yet other embodiments, relating to the use of an apparatus according to any of the embodiments herein for forming a Ti layer over an substrate and a Cu layer over the Ti layer.

Experimental tests show that comparable resistivity values and equal optimum adhesion can be achieved by sputtering two different metal layers (Ti adhesion layer, Cu seed layer) in the conventional configuration (i.e. two different process chambers) and in the neighboring cathodes configuration, wherein the rotary cathodes are isolated in the same process chamber by a separator structure.

For example, for similar substrate velocity of a dynamic sputtering process of e.g. 0.4 m/min, a chamber pressure in the range of 0.4 to 0.6 Pa, and the same sputter powers in the range of 8 kW to 11 kW for Ti and 33 kW to 36 kW for Cu, the following results shown in table 1 could be obtained. Therein, dual-sputtering=No refers to the result of the conventional sputtering in two separate vacuum chambers, wherein dual-sputtering=Yes refers to the results for two cathodes in one vacuum chamber, which have been separated by a separator plate.

TABLE 1

| Dual- | Rs | Resistivity | Adhesion |
|---|---|---|---|
| Sputtering | [mOhm/sq] | [μOhm * cm] | [B] |
| No | 44 | 2.15 | 5 |
| Yes | 48 | 2.34 | 5 |

According to yet further embodiments, which can be combined with other embodiments described herein, intermixing of different sputtered materials can be further minimized by tilting the magnet yokes in opposite directions and by rotating the rotary cathodes in opposite directions. Yet further additionally or alternatively, different rotation directions, and particularly at higher rotation speeds, e.g. of 10 rpm or above or even 20 rpm or above, result in a main or average deposition direction, which is inclined away from the separator structure which further results in reduced intermixing. Thereby, the rotation direction defines the direction of shift of the main or average deposition direction, whereas for faster rotation speeds the main or average deposition direction is shifted further, i.e. a deposition direction away from the separator can be increased by faster cathode rotation.

As described above, and shown by the results described in table 1, particularly the combination of the above mentioned technical solutions, i.e. separator structure, magnet yokes tilting, e.g. about 20° magnet yoke angle, and cathode rotation direction, enable the neighboring cathodes configuration for the deposition of multiple materials. According to yet further embodiments, which can be combined with other embodiments described herein, which mainly refer to a layer stack with two layers having different materials, the layer stack can also include more than two layers of different materials, e.g. three, four, or five layers of different materials. Thereby, typically each rotatable cathode with different target materials is separated from the neighboring cathode by a separator structure as described herein.

According to yet further uses of the embodiments described herein, the neighboring cathodes configuration with separator plate also enable the horizontal modulation of the optical and electrical film characteristics by varying the substrate transfer speed.

According to yet further embodiments, the distance of the separator structure from the substrate or the substrate support plane, i.e. the distance of the end portion of the separator structure or plate to the substrate or the substrate support plane can be described as follows, wherein L [mm] is the distance between two neighboring rotation axis of rotatable cathodes, d₁ [mm] is the distance of the separator structure to the substrate, a₁ [° ] and a₂ [° ] are the tilt angles away from the separator structure, and v₁ [rpm] and v₂ are the rotation velocity in a direction away from the separator structure on the side of the rotatable cathode facing the substrate. Thereby, please note that a₁, a₂, v₁, and v₂ change the sign in a mathematical sense depending on whether the cathode is on the left side or the right side of the separator structure. The maximum distance d1 that can be provided according to embodiments described herein as:

d₁=L*C_{L}+a₁*C_{A}+a₂*C_{A}+v₁^{*}C_{V}+v₂*C_{V}

According to some embodiments, a first constant C_{L} associated with the distance L can be in a range of 1/10 to 1/50, e.g. 1/40, a second constant C_{A} associated with the tilt angle of the yokes can be in a range of 1/2 to 1/10, e.g. 1/5 and has units [mm/° ], and a third constant C_{V} associated with the rotation speed of the cathodes can be in a range of 1/10 to 1/30, e.g. 1/20, and has units [mm/rpm]. Accordingly, the rotation direction directed away from the separator structure and the tilt of the magnet arrangements, i.e. the yokes, away from the separator structure allows for a larger distance d1 of the separator structure, e.g. a plate, from the substrate, wherein intermixing is still sufficiently reduced. The distances of the separator structure relating to the substrate support plate are increased correspondingly by adding the thickness of the substrate or a carrier in which the substrates are supported.

While the foregoing is directed to embodiments of the invention, other and further embodiments of the invention may be devised without departing from the basic scope thereof, and the scope thereof is determined by the claims that follow.

1. An apparatus for deposition of a layer stack on a non-flexible substrate or on a substrate provided in a carrier, comprising:
a vacuum chamber;
a transport system, wherein the transport system and the vacuum chamber are configured for inline deposition;
a first support for a first rotatable sputter cathode rotatable around a first rotation axis within the vacuum chamber, wherein a first deposition zone for depositing a first material is provided;
a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below;
a separator structure between the first rotation axis and the second rotation axis, adapted to receive the first material sputtered towards the second deposition zone and the second material sputtered towards the first deposition zone; and
wherein the apparatus is configured for deposition of the layer stack comprising a layer of the first material and a subsequent layer of the second material.

2. The apparatus according to claim 1, wherein the separator structure extends at least from between the first rotation axis and the second rotation axis and towards the transport system.

3. The apparatus according to claim 1, wherein the vacuum chamber comprises a first side wall and a second side wall and a chamber connection assembly having one first vacuum flange for a vacuum interconnection to an adjacent chambers at the first side wall and one second vacuum flange for a vacuum interconnection to another adjacent chambers at the second side wall.

4. The apparatus according to claim 1, wherein the vacuum chamber comprises one single vacuum flange for connection of an evacuation system.

5. The apparatus according to claim 3, wherein the separator structure has a thickness smaller than the thickness of the first and second side walls.

6. The apparatus according to claim 1, wherein the transport system is configured to provide for a deposition plane and the separator structure extends towards the deposition plane such that a distance between the separator structure and the deposition plane is 5 cm or below.

7. The apparatus according to claim 1, wherein the vacuum chamber comprises two further side walls, a bottom wall and a top wall, and wherein the separator structure is provided having a gas tight connection to one or less of the walls of the vacuum chamber.

8. The apparatus according to claim 1, wherein the first rotation axis and the second rotation axis have a distance from each other of 500 mm or below.

9. The apparatus according to claim 1, comprising the first rotatable sputter cathode and the second rotatable sputter cathode, wherein the first rotatable sputter cathode has a first magnetron magnet assembly and the second rotatable sputter cathode has a second magnetron magnet assembly, and the first magnetron magnet assembly and the second magnetron magnet assembly each have a magnet yoke angle being tilted away from the separator structure by 10° or more.

10. A system for deposition of materials on a non-flexible substrate or on a substrate provided in a carrier, comprising:
a first load lock chamber for inward transfer of the substrate into the system; and
a vacuum chamber;
a transport system, wherein the transport system and the vacuum chamber are configured for inline deposition;
a first support for a first rotatable sputter cathode rotatable around a first rotation axis within the vacuum chamber, wherein a first deposition zone for depositing a first material is provided;
a second support for a second rotatable sputter cathode rotatable around a second rotation axis within the vacuum chamber, wherein a second deposition zone for depositing a second material is provided, wherein the first rotation axis and the second rotation axis have a distance from each other of 700 mm or below;
a separator structure between the first rotation axis and the second rotation axis, adapted to receive the first material sputtered towards the second deposition zone and the second material sputtered towards the first deposition zone; and
wherein the apparatus is configured for deposition of the layer stack comprising a layer of the first material and a subsequent layer of the second material.

11. A method of depositing a layer stack on a non-flexible substrate or on a substrate provided in a carrier; comprising:
sputtering a first material layer having a first material from a first rotatable sputter cathode, wherein a first portion of the first material released from a first target of the first rotatable sputter cathode is deposited on the substrate;
sputtering a second material layer having a second material from a second rotatable sputter cathode; and
providing a separator structure, wherein the separator structure receives at least 15% of a portion of the first material other than the first portion of the first material.

12. The method according to claim 11, wherein the first material layer is selected from the group consisting of: Ti, NiV, and Mo, and the second material layer is selected from the group consisting of: Cu, Al, Au, and Ag.

13. The method according to claim 11, wherein the first rotatable sputter cathode has a first magnetron magnet assembly and the second rotatable sputter cathode has a second magnetron magnet assembly, and the first magnetron magnet assembly and the second magnetron magnet assembly each have a magnet yoke angle being tilted away from the separator structure by 10° or more.

14. The method according to claim 13, wherein the first rotatable sputter cathode has a rotation direction such that the side of the first cathode directed towards the substrate has a tangential velocity directed away from the separator structure and the second rotatable sputter cathode has a rotation direction such that the side of the second cathode directed towards the substrate has a tangential velocity directed away from the separator structure.

15. The method of claim 11, wherein the first material layer is sputtered to have a thickness of 100 nm or below, and the second material layer is subsequently sputtered onto the first material layer to have a thickness of 800 nm or below.

16. The apparatus according to claim 7, wherein the length of the separator structure is shorter as the distance of the corresponding distance between the chamber walls.

17. The apparatus according to claim 1, wherein the first rotation axis and the second rotation axis have a distance from each other of 300 mm or below.

18. The method according to claim 13, wherein the separator structure receives at least 30% of a portion of the first material other than the first portion of the first material.

19. The method according to claim 15, wherein the first material layer is selected from the group consisting of Ti, NiV, and Mo, and the second material layer is selected from the group consisting of Cu, Al, Au, and Ag.

20. The method of any of claim 13, wherein the first material layer is sputtered to have a thickness of 20 nm to 50 nm and the second material layer is subsequently sputtered onto the first material layer to have a thickness of 100 nm to 500 nm.
